(19) United States
(12) Patent Application Publication
(10) Pub. No.: US 2013/0015463 A1
(43) Pub. Date: Jan. 17, 2013

(54) NITRIDE-BASED SEMICONDUCTOR DEVICE HAVING EXCELLENT STABILITY

(71) Applicant: Jae Hoon LEE, Suwon-si (KR)

(72) Inventor: Jae Hoon LEE, Suwon-si (KR)

(73) Assignee: Samsung Electronics Co., Ltd.

(21) Appl. No.: 13/528,517

(22) Filed: Jun. 20, 2012

(30) Foreign Application Priority Data
Jul. 12, 2011 (KR) 10-2011-0068936

(51) Int. Cl. H01L 29/205

(52) U.S. Cl. 257/76; 257/E29.091

(57) ABSTRACT

A nitride-based semiconductor device is provided. The nitride-based semiconductor device may include an aluminum silicon carbide (AlSiₓC₁₋ₓ) pre-treated layer, and thus may ease a stress in a nitride semiconductor layer caused by a difference in properties, for example, a lattice constant and a coefficient of expansion, between the substrate and the nitride semiconductor layer formed on the substrate. Accordingly, an incidence of cracks created in the nitride semiconductor layer may be minimized and a surface roughness of the nitride semiconductor layer may be improved and thus, stability and performance of the nitride-based semiconductor device may be improved. The nitride-based semiconductor device may include a grade AlGaN layer of which an aluminum (Al) content gradually decreases from the substrate and thus, an incidence of cracks created in the nitride semiconductor layer may be minimized and the nitride semiconductor layer having a stable structure may be formed.

### CROSS-REFERENCE TO RELATED APPLICATION

This application claims the benefit of Korean Patent Application No. 10-2011-0068936, filed on Jul. 12, 2011, in the Korean Intellectual Property Office, the disclosure of which is incorporated herein by reference.

### BACKGROUND

1. Field of the Invention

The present invention relates to a nitride-based semiconductor device having an excellent stability, and more particularly, to a nitride-based semiconductor device, having an improved stability, which has few cracks in a nitride semiconductor layer and has an excellent surface roughness.

2. Description of the Related Art

As information communication technologies have been considerably developed globally, communication technologies for high-speed and large-capacity signal communication have been rapidly developed. In particular, as demand for a personal cellular phone (PCS), a satellite communication, a military radar, a broadcasting communication, a communication relay, and the like in wireless communication technology has increased, demands for a high speed and power electronic device required for a high-speed information communication system of a microwave band and a millimeter-wave band have increased. Consequently, research on a power device for high power electric devices, and on power consumption is being actively conducted.

Particularly, since a GaN-based nitride semiconductor has advantageous properties, such as a high energy gap, a high heat stability, a high chemical stability, a high electronic saturation velocity of about 3×10⁷ centimeters per second (cm/sec), the nitride semiconductor may be readily utilized as a light device, and a high frequency and a high power electronic device. Accordingly, research on the nitride semiconductor is being actively conducted the world over.

An electronic device based on the GaN-based nitride semiconductor may have varied advantages, for example, a high breakdown field of about 3×10⁶ volts per centimeter (V/cm), a maximum current density, a stable high temperature operation, a high heat conductivity, and the like. A heterostructure field effect transistor (HFET) generated based on a heterojunction of aluminum gallium nitride (AlGaN) and gallium nitride (GaN) has a high band-discontinuity at a junction interface, a high-density of electrons may be freed in the interface and thus, an electron mobility may increase. Accordingly, the HFET may be applicable as the high-power device.

However, a substrate for growing a nitride single crystal that is appropriate for a lattice constant and a thermal expansion coefficient of the nitride single crystal is not widespread. The nitride single crystal may grow on a hetero-substrate, for example, a sapphire substrate or a silicon carbide (SiC) substrate, based on a molecular beam epitaxy (MBE) scheme or a vapor phase epitaxy, for example, a meta organic chemical vapor deposition (MOCVD) scheme, a hydride vapor phase epitaxy (HVPE) scheme, and the like. The sapphire substrate or the SiC substrate is expensive and their sizes are limited and thus, the sapphire substrate or the SiC substrate is not appropriate for mass production. Therefore, a Si substrate may be a substrate that is readily used for mass production for improving productivity through enlarging a size of a substrate, in addition to improving of a heat conductivity. However, due to a difference in a lattice constant and a difference in a coefficient of expansion between the Si substrate and the GaN single crystal, cracks may be easily formed in a GaN layer thereby making commercialization difficult. There is a desire for a method of stably growing GaN on the Si substrate.

FIG. 1 illustrates a basic configuration of a conventional nitride-based HFET.

Referring to FIG. 1, the conventional nitride-based HFET 10 may include a low-temperature buffer layer 12, AlGaN/GaN complex layer 13, a non-doped GaN layer 14, and AlGaN layer 15 are sequentially layered on the Si substrate 11. A source electrode 16 and a drain electrode 18 are formed on both ends of an upper surface of the AlGaN layer 15, respectively. A gate electrode 17 is disposed between the source electrode 16 and the drain electrode 18. A protective layer 19 is formed between the gate electrode 17 and the source electrode 16, and between the gate electrode 17 and drain electrode 18. The AlGaN/GaN complex layer 13 is formed to include a plurality of layers, and a GaN layer may grow on the AlGaN/GaN complex layer 13 by decreasing the difference in the lattice coefficient.

In the conventional nitride-based HFT 10, a 2-dimensional electron gas (2-DEG) layer may be formed based on a heterojunction of the GaN layer 14 and the AlGaN layer 15 which have different band-gaps. Here, when a signal is inputted to the gate electrode 17, a channel may be formed by the 2-DEG layer so that a current may flow between the source electrode 16 and the drain electrode 18. The non-doped GaN layer 14 may be configured as a GaN layer to which doping is not performed, and may be formed to have a relatively high resistance so as to prevent a leakage current to the Si substrate to separate devices.

### SUMMARY

An aspect of the present invention provides a nitride-based semiconductor device, having an improved stability, which has few cracks in a nitride semiconductor layer and has an excellent surface roughness.

According to an aspect of the present invention, there is provided a nitride-based semiconductor device, including a substrate, an aluminum silicon carbide (AlSiₓC₁₋ₓ) pre-treated layer formed on the substrate, an aluminium (Al)-doped gallium nitride (GaN) layer, formed on the AlSiₓC₁₋ₓ pre-treated layer, and an aluminum gallium nitride (AlGaN) layer formed on the Al-doped GaN layer.

The AlSiₓC₁₋ₓ pre-treated layer may be configured as a structure selected from a single bed structure, a regular dot pattern structure, an irregular dot pattern structure, and a pattern structure.

The nitride-based semiconductor device may further include a buffer layer formed on the AlSiₓC₁₋ₓ pre-treated layer, and the buffer layer may include aluminum nitride (AlN).

The nitride-based semiconductor device may further include a GaN seed layer of which a group V/III ratio indicating a ratio of a group V element to a group III element is adjusted, formed between the AlSiₓC₁₋ₓ pre-processing layer and the Al-doped GaN layer.

The GaN seed layer may include a first GaN seed layer of which the group V/III ratio is relatively high, and a second GaN seed layer of which the group V/III ratio is relatively low.

The nitride-based semiconductor device may further include a grade AlGaN layer formed between the AlSiₓC₁₋ₓ pre-treated layer and the Al-doped GaN layer, and an Al content of the grade AlGaN layer may gradually decrease from the AlSiₓC₁₋ₓ pre-treated layer to the Al-doped GaN layer.

The Al content in the grade AlGaN layer may decrease in a range from about 70% to 15%.

The Al-doped GaN layer may have an Al content in a range from about 0.1% to 0.9%.

The nitride-based semiconductor device may further include a protective layer formed on the AlGaN layer, and the protective layer may include a material selected from one of silicon nitride (SiNₓ), silicon oxide (SiOₓ), and aluminum oxide (Al₂O₃).

The substrate may include a material selected from sapphire, silicone (Si), AlN, silicon carbide (SiC), and GaN.

The nitride-based semiconductor device may be a device selected from a normally-ON device, a normally-OFF device, and a Schottky diode.

The nitride based semiconductor device may include a first conductive semiconductor layer, an active layer, and a second conductive semiconductor layer.

Additional aspects, features, and/or advantages of the invention will be set forth in part in the description which follows and, in part, will be apparent from the description, or may be learned by practice of the invention.

### BRIEF DESCRIPTION OF THE DRAWINGS

The patent or application file contains at least one drawing executed in color. Copies of this patent or patent application publication with color drawing(s) will be provided by the Office upon request and payment of the necessary fee. These and/or other aspects, features, and advantages of the invention will become apparent and more readily appreciated from the following description of embodiments, taken in conjunction with the accompanying drawings of which:

FIG. 1 is a diagram illustrating a basic configuration of a heterostructure field effect transistor (HFET) according to a conventional art;

FIG. 2 is a cross-sectional view of a HFET according to an embodiment of the present invention;

FIG. 3 is a cross-sectional view of a Schottky diode according to an embodiment of the present invention;

FIG. 4 is a cross-sectional view of a semiconductor light emitting device according to an embodiment of the present invention;

FIG. 5A is an optical image of a surface of an aluminum (Al) pre-treated nitride semiconductor before a buffer is grown on a substrate, according to an embodiment of the present invention;

FIG. 5B is an optical image of a surface of an aluminum silicon carbide (AlSiₓC₁₋ₓ) pre-treated nitride semiconductor according to an embodiment of the present invention;

FIG. 6 is a graph of an X-ray diffraction analysis value of a surface of an Al pre-treated nitride semiconductor before a buffer is grown on a substrate and an X-ray diffraction analysis value of a surface of an AlSiₓC₁₋ₓ pre-treated nitride semiconductor according to an embodiment of the present invention;

FIG. 7 is a graph of an X-ray diffraction analysis data (omega-2theta) of an AlSiₓC₁₋ₓ pre-treated nitride semiconductor according to an embodiment of the present invention;

FIG. 8 is a graph of mapping data associated with a thickness of an entire AlSiₓC₁₋ₓ pre-treated nitride semiconductor according to an embodiment of the present invention; and

FIG. 9 is a diagram illustrating an optical image and a microscopic image of an AlSiₓC₁₋ₓ pre-treated nitride semiconductor according to an embodiment of the present invention.

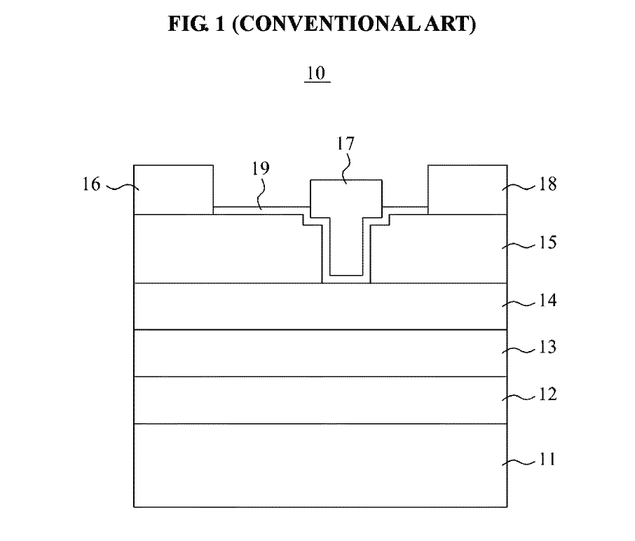

### DETAILED DESCRIPTION

Reference will now be made in detail to embodiments of the present invention, examples of which are illustrated in the accompanying drawings, wherein like reference numerals refer to the like elements throughout. Embodiments are described below to explain the present invention by referring to the figures.

Throughout the specifications, when it is described that each of a layer, a side, a chip, and the like is formed “on” or “under” a layer, a side, a chip, and the like, the term “on” may include “directly on” and “indirectly on,” and the term “under” may include “directly under” and “indirectly under.” A standard for “on” or “under” of each element may be determined based on a corresponding drawing.

A size of each element in drawings may be exaggerated for ease of descriptions, and does not indicate a real size.

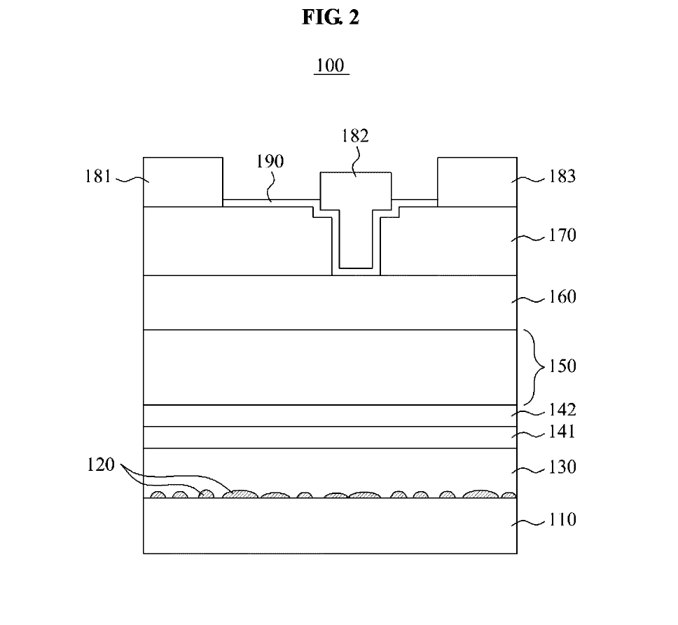

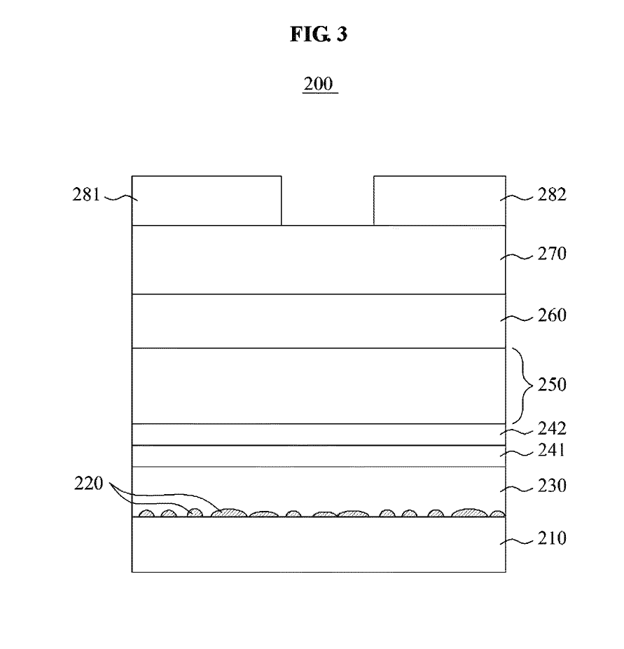

FIG. 2 illustrates a cross-section of a heterostructure field effect transistor (HFET) 100 according to an embodiment of the present invention. FIG. 3 illustrates a cross-section of a Schottky diode 200 according to an embodiment of the present invention.

A nitride-based semiconductor device according to an embodiment of the present invention may be applied to the HFET 100, the Schottky diode 200, and a semiconductor light emitting device 300. The nitride-based semiconductor device may be a device selected from a normally ON device, a normally OFF device, and the Schottky diode, and may be a semiconductor light emitting device including a first conductive semiconductor layer, an active layer, and a second conductive semiconductor layer.

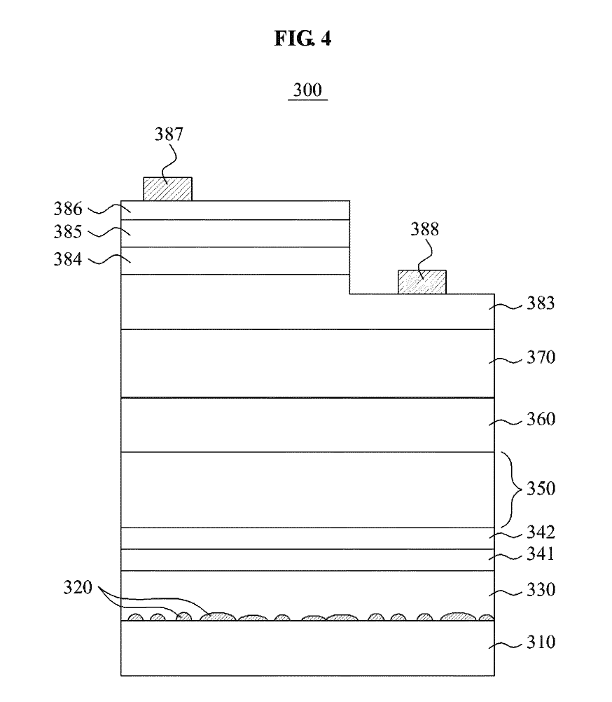

Referring to FIGS. 2 through 4, although like elements perform the same functions, the like elements may have different references for each each drawing, for example, substrates 110, 210, and 310, aluminum silicon carbide (AlSiₓC₁₋ₓ) pre-treated layers 120, 220, and 320, buffer layers 130, 230, and 330, gallium nitride (GaN) seed layers 141, 142, 241, 242, 341, and 342, grade aluminum gallium nitride (AlGaN) layers 150, 250, and 350, aluminum (Al)-doped GaN layers 160, 260, and 360, and AlGaN layers 170, 270, and 370. For ease of descriptions, each element will be described with reference to FIG. 2 and like elements once described in foregoing descriptions will be omitted in descriptions of FIGS. 3 and 4 for clarity and conciseness.

Referring to FIG. 2, the nitride-based semiconductor device according to an embodiment may include the substrate 110, the AlSiₓC₁₋ₓ pre-treated layer 120, the Al-doped GaN layer 160 formed on the AlSiₓC₁₋ₓ pre-treated layer 120, and the AlGaN layer 170 formed on the Al-doped GaN layer 160.

The nitride-based semiconductor device may further include the buffer layer 130, the GaN seed layer 140, and the grade AlGaN layer 150.

The substrate 110 may include a material selected from sapphire, silicone (Si), aluminum nitride (AlN), silicone carbide (SiC), and GaN. That is, the substrate 110 may be an insulating substrate, for example, a glass substrate or a sapphire substrate, and may be a conductive substrate, for example, Si, SiC, and zinc oxide (ZnO). The substrate 100 may be a substrate for growing nitride, for example, an AlN-based substrate or a GaN-based substrate.

The AlSiₓC₁₋ₓ pre-treated layer 120 may ease a stress in a nitride semiconductor layer caused by a difference in a lattice constant, a coefficient of expansion, and the like between the substrate 110 and the nitride semiconductor layer formed on the substrate 110. Accordingly, an incidence of cracks created in the nitride semiconductor layer may be minimized and a surface roughness of the nitride semiconductor layer may be improved, so that a stability and a performance of the nitride-based semiconductor device may be improved.

The AlSiₓC₁₋ₓ pre-treated layer 120 may be configured as a structure selected from a regular dot structure, an irregular dot structure, and a pattern structure, and the structure may not be limited thereto. The AlSiₓC₁₋ₓ pre-treated layer 120 may be configured as varied structures and shapes, so as to minimize an incidence of cracks created in the nitride semiconductor layer and to improve a surface roughness of the nitride semiconductor layer.

The buffer layer 130 may be formed on the AlSiₓC₁₋ₓ pre-treated layer 120. The buffer layer 130 may include AN. The buffer layer 130 may be formed as a single crystal having a thickness in a range from about 20 nanometers (nm) to 1000 nm. The buffer layer 130, together with the AlSiₓC₁₋ₓ pre-treated layer 120, may minimize a difference in a lattice constant and a coefficient of expansion between the substrates and the nitride-based semiconductor layer and thus, may improve a stability and a performance of the nitride-based semiconductor device.

A GaN seed layer, for example, the first GaN seed layer 141 and the second GaN seed layer 142, may be formed on the buffer layer 130. The GaN seed layer may include a group V element and a group III element so as to stably form a nitride-based semiconductor layer. Here, the nitride semiconductor layer may include the grad AlGaN layer 150, the Al-doped GaN layer 160, and the AlGaN layer 170. The GaN seed layer may promote vertical growth of the nitride-based semiconductor layer so as to improve efficiency in manufacturing of a nitride-based semiconductor device and a quality of the nitride-based semiconductor device. The GaN seed layer may adjust a group V/III ratio indicating a ratio of a group V element to a group III element.

The GaN seed layer may be configured as two layers including the first GaN seed layer 141 having a high V/III group ratio and the second GaN seed layer 142 having a low V/III group ratio. The first GaN seed layer 141 may be formed on the buffer layer 130, and may be formed in a condition of a high pressure and a high V/III group ratio. For example, the first GaN seed layer 141 may be formed in a condition of a pressure greater than or equal to 300 Ton and the V/III group ratio greater than or equal to 10,000 Torr.

The second GaN seed layer 142 may be formed on the first GaN seed layer 141, and may be formed in a condition of a low pressure and a low V/III group ratio. For example, the second GaN seed layer 142 may be formed in a condition of a pressure less than or equal to 50 Ton and the V/III group ratio less than or equal to 3,000.

The grade AlGaN layer 150 may be formed between the AlSiₓC₁₋ₓ pre-treated layer 120 and the Al-doped GaN layer 160. An Al content of the grade AlGaN layer 150 may gradually decrease from the AlSiₓC₁₋ₓ pre-treated layer 120 to the Al-doped GaN layer 160. The Al content in the grade AlGaN layer 150 may decrease in a range from about 70% to 15%.

The grade AlGaN layer 150 may be configured as multiple layers, and respective Al contents of the multiple layers may be different from each other. For example, the AlGaN layer 150 may be configured to include a first grade AlGaN layer (not illustrated) of which an Al content decreases in a range from about 70% to 50%, a second grade AlGaN layer (not illustrated) of which an Al content decreases in a range from about 50% to 30%, a third grade AlGaN layer (not illustrated) of which an Al content decreases in a range from about 30% to 15%, which are sequentially layered. Therefore, the AlGaN layer 150 of which an Al content gradually decreases to the Al-doped GaN layer 160 may be formed, so as to form a nitride semiconductor layer that has a stable structure, and that prevents cracks from being created.

The multiple layers of the grade AlGaN layer 150 may have a thickness appropriate for minimizing an incidence of cracks created in the nitride semiconductor layer and for providing a stable structure to the nitride semiconductor layer. For example, an AlGaN layer having an Al content of about 70% in the first grade AlGaN layer may be formed to have a thickness in a range from about 20 nm to 1000 nm, and the entire second grade AlGaN layer may be formed to have a thickness in a range from about 20 nm to 50 nm.

The Al-doped GaN layer 160 may be formed on the grade AlGaN layer 150. The Al-doped GaN layer 160 may contain Al in a range from about 0.1% to 0.9%. Desirably, the Al-doped GaN layer 160 may contain Al in a range from about 0.3% to 0.6%. The Al-doped GaN layer 160 may passivate a Ga vacancy that may be a defect in the GaN layer caused by Al. Accordingly, a crystallizability of the GaN layer may be improved by repressing growth to a two-dimensional (2D) or three-dimensional (3D) electric potential.

The AlGaN layer 170 may be formed on the Al-doped GaN layer 160. The protective layer 190 may be further formed on the AlGaN layer 170. The protective layer 190 may include a material selected from silicone nitride (SiNₓ), silicon oxide (SiOₓ), and aluminum oxide (Al₂O₃). The protective layer 190 may be a passivation thin-film layer, may reduce an unstability of a surface of the AlGaN layer, and may reduce a decrease in a characteristic of power caused by a current collapse during a high frequency operation.

The nitride-based semiconductor device according to an aspect of the present invention may be applied to various types of electric devices.

As shown in FIG. 2, the nitride-based semiconductor device may be applicable to a normally-ON device and a normally-OFF device, which are HFETs including a source electrode 181, a gate electrode 182, and a drain electrode 183. The source electrode 181 and the drain electrode 183 may include a material selected from chromium (Cr), Al, tantalum (Ta), titanium (Ti), and gold (Au).

As shown in FIG. 3, the nitride-based semiconductor device may be applicable to a Schottky diode including an ohmic electrode 281 and a schottky electrode 282. The ohmic electrode 281 may include a material selected from Cr, Al, Ta, Ti, and Au. The Schottky electrode 282 may include a material selected from nickel (Ni), Au, copper indium oxide (CuInO₂), indium tin oxide (ITO), platinum (Pt), and alloys thereof. Examples of the alloys may include an alloy of Ni and Au, an alloy of CuInO₂ and Au, and an alloy of ITO and Au, an alloy of Ni, Pt, and Au, and an alloy of Pt and Au, and the examples may not limited thereto.

As shown in FIG. 4, the nitride-based semiconductor device may be applicable to a semiconductor light emitting device including a first conductive semiconductor layer 383, an active layer 384, and a second conductive semiconductor layer 385. The active layer 384 may have a quantum wall structure in the semiconductor light emitting device, and the semiconductor light emitting device may include a transparent electrode 386, a p-type electrode 387, and an n-type electrode 388.

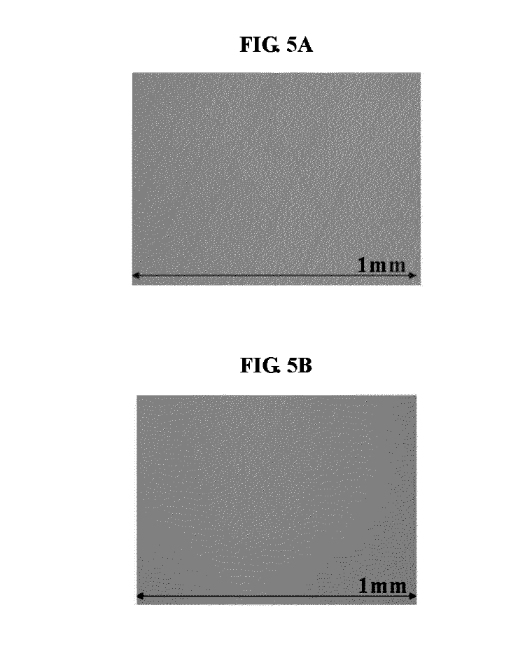

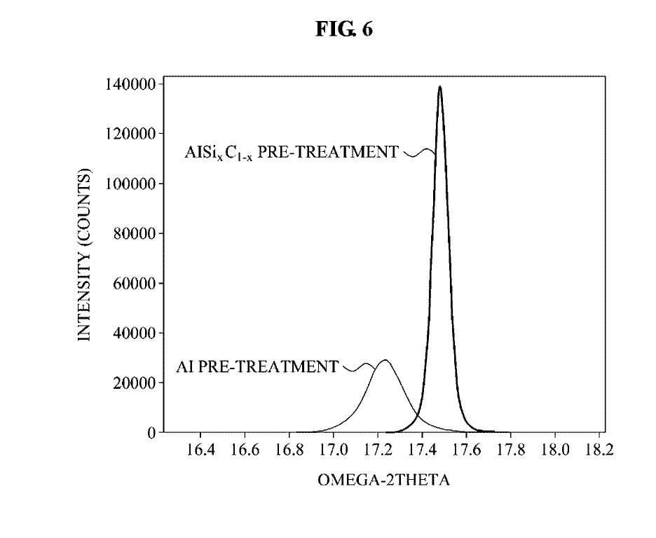

FIG. 5A illustrates an optical image of a surface of an Al pre-treated nitride semiconductor before a buffer is grown on a substrate, according to an embodiment of the present invention, and FIG. 5B illustrates an optical image of a surface of an AlSiₓC₁₋ₓ pre-treated nitride semiconductor according to an embodiment of the present invention. FIG. 6 illustrates a graph of an X-ray diffraction analysis value of a surface of an Al pre-treated nitride semiconductor before a buffer is grown on a substrate and an X-ray diffraction analysis value of a surface of an AlSiₓC₁₋ₓ pre-treated nitride semiconductor according to an embodiment of the present invention.

Referring to FIGS. 5A and 5B, fine cracks are created in the surface of the Al pre-treated nitride semiconductor before the buffer is grown, whereas the surface of AlSiₓC₁₋ₓ pre-treated nitride semiconductor does not include a crack.

Referring to FIG. 6, the X-ray diffraction analysis value of the Al pre-treated nitride semiconductor indicates 716 arcseconds (arcsec), whereas the X-ray diffraction analysis value of the AlSiₓC₁₋ₓ pre-treated nitride semiconductor decreases to 313 arcsec. Accordingly, AlSiₓC₁₋ₓ pre-treatment may ease a stress of a nitride semiconductor, may decrease an incidence of cracks, and may improve crystallizability.

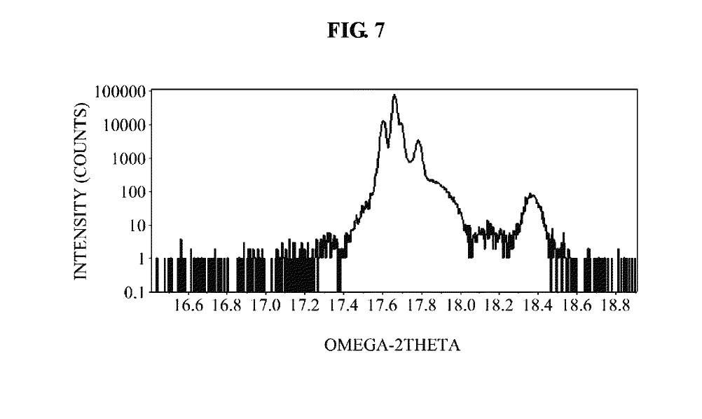

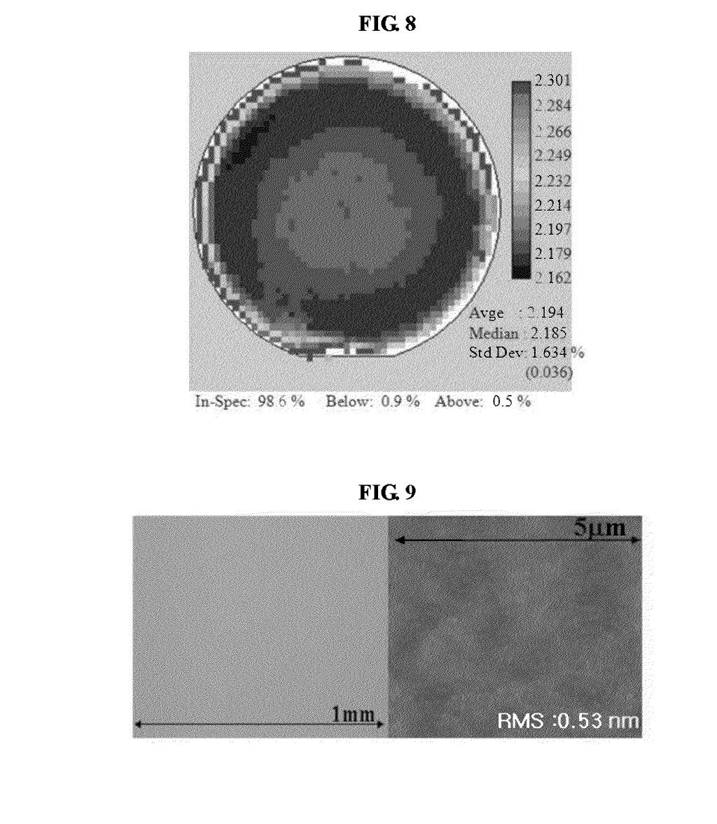

FIG. 7 illustrates an X-ray diffraction analysis data (omega-2theta) of an AlSiₓC₁₋ₓ pre-treated nitride semiconductor according to an embodiment of the present invention. FIG. 8 illustrates mapping data associated with a thickness of an entire AlSiₓC₁₋ₓ pre-treated nitride semiconductor according to an embodiment of the present invention. FIG. 9 illustrates an optical image and a microscopic image of an AlSiₓC₁₋ₓ pre-treated nitride semiconductor according to an embodiment of the present invention.

Referring to FIG. 7, peaks associated with an Al content in a nitride-based semiconductor device are shown. Referring to FIGS. 8 and 9, the nitride-based semiconductor device has few cracks and has a superior surface of roughness of 0.53 nm, observed by a microscope, since the nitride-based semiconductor device includes an AlSiₓC₁₋ₓ pre-treated layer and a GaN seed layer of which a V/III group ratio is adjusted.

Conventionally, growing of a nitride-based semiconductor layer to at least a predetermined thickness has been difficult. However, the nitride-based semiconductor device according to an embodiment of the present invention may include the AlSiₓC₁₋ₓ pre-treated layer on the substrate and thus, may grow the nitride semiconductor layer to at least a predetermined thickness with few cracks. As shown in FIG. 8, the nitride-based semiconductor device may have few cracks, may have the entire thickness of 2.2 μm, and have a relatively constant thickness with a deviation of about 1.6%.

In the nitride-based semiconductor device according to an embodiment of the present invention, when an Al content of an AlGaN layer formed on an Al-doped GaN layer is about 40%, a mobility of a two-dimensional electron gas (2-DEG) layer may be about 1000 centimeters squared per volt-second (cm²/Vs) and a sheet carrier density may be about 1.5×10¹³/cm².

The nitride-based semiconductor device according to an embodiment of the present invention may include the AlSiₓC₁₋ₓ pre-treated layer and thus, may relax a stress in a nitride semiconductor layer caused by difference in properties, for example, a lattice constant and a coefficient of expansion, between the substrate and the nitride semiconductor layer formed on the substrate. Accordingly, an incidence of cracks created in the nitride semiconductor layer may be minimized and a surface roughness of the nitride semiconductor layer may be improved and thus, a stability and a performance of the nitride-based semiconductor device may be improved.

The nitride-based semiconductor device according to an embodiment of the present invention may include a grade AlGaN layer of which an Al content gradually decreases from the substrate and thus, an incidence of cracks created in the nitride semiconductor layer may be minimized and the nitride semiconductor layer having a stable structure may be formed.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

What is claimed is:

1. A nitride-based semiconductor device, comprising:
a substrate;
an aluminum silicon carbide (AlSiₓC₁₋ₓ) pre-treated layer formed on the substrate;
an aluminum (Al)-doped gallium nitride (GaN) layer, formed on the AlSiₓC₁₋ₓ pre-treated layer; and
an aluminum gallium nitride (AlGaN) layer formed on the Al-doped GaN layer.

2. The nitride-based semiconductor device of claim 1, wherein the AlSiₓC₁₋ₓ pre-treated layer is configured as a structure selected from a group consisting of a single bed structure, a regular dot pattern structure, an irregular dot pattern structure, and a pattern structure.

3. The nitride-based semiconductor device of claim 1, further comprising:
a buffer layer formed on the AlSiₓC₁₋ₓ pre-treated layer,
wherein the buffer layer comprises aluminum nitride (AlN).

4. The nitride-based semiconductor device of claim 1, further comprising:
a GaN seed layer of which a group V/III ratio indicating a ratio of a group V element to a group III element is adjusted, formed between the AlSiₓC₁₋ₓ pre-processing layer and the Al-doped GaN layer.

5. The nitride-based semiconductor device of claim 4, wherein the GaN seed layer comprises:
a first GaN seed layer of which the group V/III ratio is relatively high; and
a second GaN seed layer of which the group V/III ratio is relatively low.

6. The nitride-based semiconductor device of claim 1, further comprising:
a grade AlGaN layer formed between the AlSiₓC₁₋ₓ pre-treated layer and the Al-doped GaN layer,
wherein an Al content of the grade AlGaN layer gradually decreases from the AlSiₓC₁₋ₓ pre-treated layer to the Al-doped GaN layer.

7. The nitride-based semiconductor device of claim 6, wherein the Al content in the grade AlGaN layer decreases in a range from about 70% to 15%.

8. The nitride-based semiconductor device of claim 1, wherein the Al-doped GaN layer has an Al content in a range from about 0.1% to 0.9%.

9. The nitride-based semiconductor device of claim 1, further comprising:
a protective layer formed on the AlGaN layer,
wherein the protective layer comprises a material selected from a group consisting of silicon nitride (SiNₓ), silicon oxide (SiOₓ), and aluminum oxide (Al₂O₃).

10. The nitride-based semiconductor device of claim 1, wherein the substrate comprises a material selected from a group consisting of sapphire, silicone, AN, silicon carbide (SiC), and GaN.

11. The nitride-based semiconductor device of claim 1, wherein the nitride-based semiconductor device is a device selected from a group consisting of a normally-ON device, a normally-OFF device, and a Schottky diode.

12. The nitride-based semiconductor device of claim 11, wherein an ohmic electrode in the Schottky diode comprises a material selected from a group consisting of chromium (Cr), Al, tantalum (Ta), titanium (Ti), and gold (Au).

13. The nitride-based semiconductor device of claim 11, wherein a Schottky electrode in the Schottky diode comprises a material selected from a group consisting of nickel (Ni), Au, copper indium oxide (CuInO₂), indium tin oxide (ITO), platinum (Pt) and alloys thereof.

14. The nitride-based semiconductor device of claim 1, wherein the nitride based semiconductor device comprises a first conductive semiconductor layer, an active layer, and a second conductive semiconductor layer.
